(19) United States
(12) Patent Application Publication
(10) Pub. No.: US 2009/0294483 A1
(43) Pub. Date: Dec. 3, 2009

(54) CONTAINER FOR AUTOMATICALLY DISPENSING PASTE IN A PASTE PRINTER

(76) Inventor: Kyoung Dae Kim, Gwangmyeong-si (KR)

Correspondence Address: Workman Nydegger;1000 Eagle Gate Tower, 60 East South Temple, Salt Lake City, UT, 84111, US

(21) Appl. No.: 12/169,488

(22) Filed: Jul. 8, 2008

(30) Foreign Application Priority Data
May 29, 2008 (KR) 10-2008-0050364

(51) Int. Cl. G01F 11/00

(52) U.S. Cl. 222/386

(57) ABSTRACT

The present invention relates to a container for holding paste used for making reflow soldering to fix surface mounted components (semiconductors, diodes, resistors, and so on) to a circuit on a printed circuit board. More specifically, the present invention relates to a container for automatically dispensing paste in a paste printer which can make automatic fixed amount dispensing of paste to a stencil of the paste printer. The container comprises a body including an opening, a supply hole in a center of a bottom for supply of the paste, and a press member movably mounted in the body and including a rim, and a sloped portion and a deforming portion both continuous from the rim inwardly, thereby making automatic dispensing of the paste to the upper surface of the stencil through the supply hole.

### CROSS-REFERENCE TO RELATED APPLICATIONS

The present invention claims the benefit of priority under 35 U.S.C. § 119 to Korean Patent Application No. 10-2008-0050364, filed on May 29, 2008, having a translated title of “CONTAINER FOR AUTOMATICALLY DISPENSING PASTE IN A PASTE PRINTER,” the content of which is incorporated herein by reference in its entirety.

### BACKGROUND OF THE INVENTION

1. The Field of the Invention

The present invention relates to a container for paste used to make reflow soldering to fix surface mounted components (semiconductors, diodes, resistors, etc.) on a circuit on a printed circuit board. More specifically, the present invention relates to a container for automatically dispensing paste to a stencil of a paste printer.

2. The Relevant Technology

In general, in order to make automatic mounting of a component by using a surface mounting device (SMD), it is required to apply paste to a required thickness in the same shape as a pad on the printed circuit board the component to be mounted thereon.

Accordingly, it is required that the paste is automatically printed on the surface of the printed circuit board in the same shape as the component to be mounted thereon by using the paste printer in an entire process of the surface mounting device.

FIG. 1 illustrates an operation principle of the paste printer schematically, and FIG. 2 illustrates a top view of one example of a stencil used for a paste printer, wherein pass through holes 2a in the stencil 2 having the same shapes with pads 1a printed on a surface of the printed circuit board 1 are formed as shown in FIG. 2, and a squeegee 4 is mounted on the stencil to be movable back and forth to scratch the paste 3 applied to the stencil 2 to print the paste on the pad 1a in the same shape as the pass through hole 2a.

Accordingly, upon putting the squeegee into operation after manual or automatic introduction of the printed circuit board 1 under the stencil 2 having the pads 1a thereon facing upward and dipping out and manual application of a fixed amount of the paste 3 from a container (not shown) to an upper surface of the stencil 2, the squeegee moves along the upper surface of the stencil 2, scratching the paste 3 from the upper surface of the stencil 2 to transfer a fixed amount of the paste to the pads 1a on the printed circuit board 1 through the pass through holes 2a in the stencil 2 in a predetermined thickness. Then, in a following component surface mounting process, the surface mounting device mounts the component on the upper surface of the paste automatically, and in a final process of the reflow soldering, the mounted components Mare soldered automatically.

FIG. 3 illustrates a longitudinal section of the related art paste container 5 for holding the paste 3, provided with an opening 5a closed with a cover 6 so that the worker is required to open the cover 6, dip out the paste 3 from the container 5 though the opening 5a, and supply the paste 3 to an upper side of the stencil 2 manually for the transfer of the paste later.

However, the worker's manual dipping out and supply of the paste from the container to the stencil in the paste printer requires a man assigned for the supply of the paste without fail, thereby increasing production costs due to additional labor cost and increasing failure of automation of an expensive apparatus.

Moreover, the dependence of the amount of paste supplied to the upper surface of the stencil on skill of the worker deteriorates the uniformity of quality of products.

Accordingly, object of the present invention is to provide a container for automatically dispensing paste in a paste printer, which can automatically dispense a fixed amount of paste to an upper surface of a stencil of the paste printer by using separate driving means once the container is loaded over the stencil of the paste printer while the container serves as a container for holding paste in a general storage state.

Another object of the present invention is to provide a container for automatically dispensing paste in a paste printer, which can automatically dispense a fixed amount of paste for reducing a labor cost, and realizing automation of an expensive apparatus to enable mass production of good quality products.

### BRIEF SUMMARY OF THE INVENTION

To achieve these objects and other advantages and in accordance with the purpose of the invention, as embodied and broadly described herein, a container for automatically dispensing paste in a paste printer to an upper surface of a stencil comprises a body including an opening, a supply hole in a center of a bottom for supply of the paste, and a cap for closing the supply hole in case of storage or transportation, and opening the supply hole in case of loading the body on the paste printer, and a press member movably mounted in the body, including a rim, and a sloped portion and a deforming portion both continuous from the rim inwardly, for serving as a cover in storage and transportation and moving inwardly by a pressing force of a pusher such that the rim is in close contact with an inside surface of the body for the press member to serve as a piston in a state the container is loaded on the paste printer, thereby making automatic dispensing of the paste to the upper surface of the stencil through the supply hole.

The present invention has following advantageous effects.

First, the closure of the supply hole in the center of the bottom of the body with the cap and the press member covering the body in a general state permits safe storage and transportation of the paste.

Second, if the cap is removed from the supply hole, the body is loaded on the paste printer, and the press member is pressed down with the pusher, the press member serves as a piston by a pressing force of the pusher and it permits automatic dispensing of the paste to the upper surface of the stencil without addition of worker, thereby reducing production costs.

Third, the automatic dispensing of the paste to the upper side of the stencil permits improvement of quality.

These and other objects and features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only illustrated embodiments of the invention and are therefore not to be considered limiting of its scope. The invention will be described and explained with additional specificity and detail through the use of the accompanying drawings in which:

FIG. 1 illustrates a principle of a paste printer, schematically;

FIG. 2 illustrates a plan view an exemplary stencil used for a paste printer;

FIG. 3 illustrates a longitudinal section of a related art paste container;

FIG. 4 illustrates a perspective sectional view of a container in accordance with one embodiment of the present invention;

FIGS. 5A and 5B illustrate cross sectional views of the container in FIG. 4 respectively, wherein

FIG. 5A illustrates a cross sectional view of the container in FIG. 4 with the paste filled therewith, and

FIG. 5B illustrates a cross sectional view of the container in FIG. 4 with the paste pressed down by a pressing member pushed with a pusher in a state a supply hole is opened;

FIG. 6 illustrates a cross sectional view of a pressing member in accordance with an embodiment of the present invention; and

FIG. 7 illustrates a partial section of a body of a container in accordance with an embodiment of the present invention.

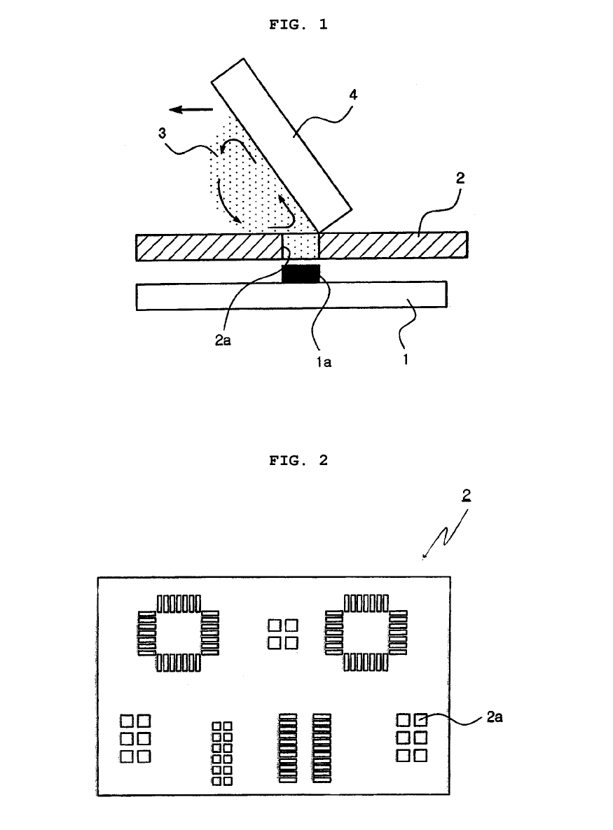

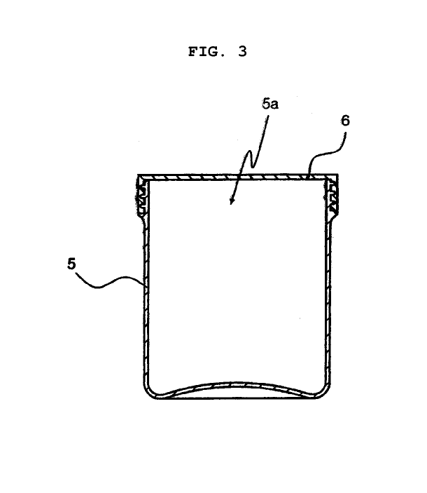

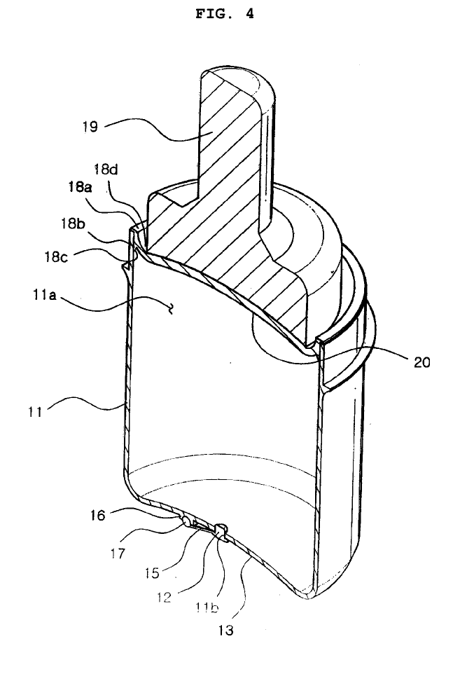

### DETAILED DESCRIPTION OF THE PREFERRED EMBODIMENTS

Reference will now be made in detail to the specific embodiments of the present invention, examples of which are illustrated in the accompanying drawings FIGS. 4 to 7. Wherever possible, the same reference numerals will be used throughout the drawings to refer to the same or like parts.

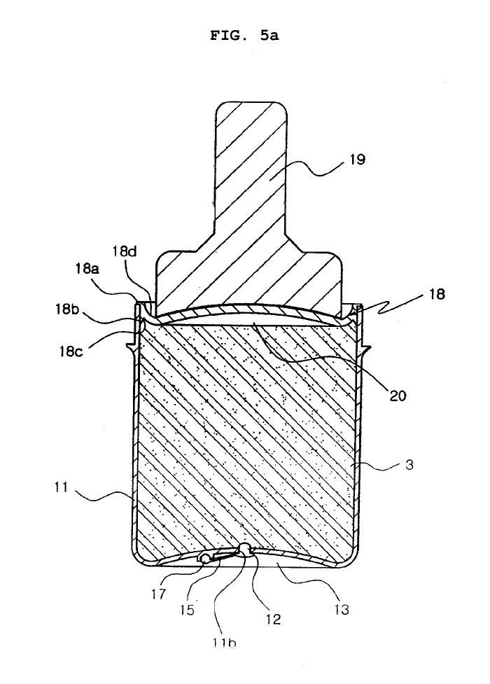

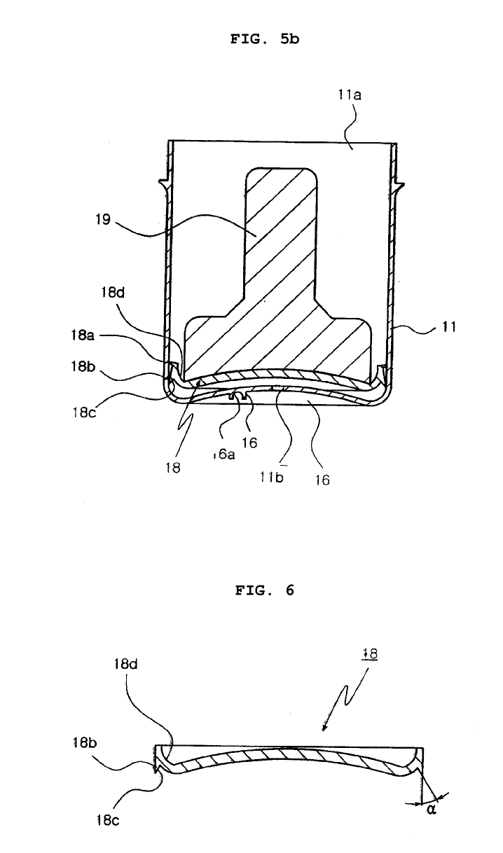

FIG. 4 illustrates an exploded perspective view of a container in accordance with an embodiment of the present invention, and FIGS. 5A and 5B illustrate cross sectional views of the container in FIG. 4 respectively.

Referring to FIGS. 4, 5A and 5B, the container includes a body 11 having an opening 11a and a supply hole 11b in a center of a bottom for supply of paste 3, with a cap 12 for closing the supply hole 11b in case of storage or stop of operation to prevent the paste from being discharged from the container, and opening in case of loading the body 11 on the paste printer (not shown) to dispense a fixed amount of the paste.

Since the cap 12 opens/closes the supply hole 11b in the center of the bottom of the body 11, the bottom of the body 11 is required to be flat even if the supply hole 11b in the body 11 is closed for convenience of use and storage.

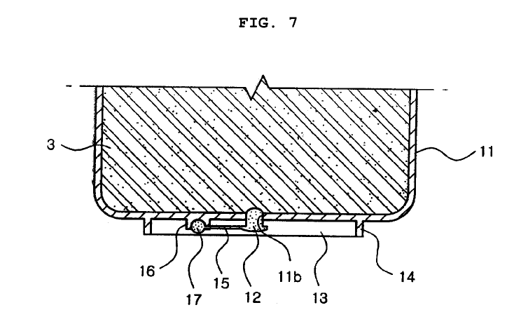

Therefore, the bottom of the body 11 is curved inwardly to form a recessed portion 13 as shown in FIGS. 4 and 5, or an annular rim 14 is projected from the bottom of the body 11 as shown in FIG. 7 and the cap 12 closes the supply hole 11b.

According to this, even if the supply hole 11b is closed with the cap 12, the cap 12 does not project beyond a bottom surface of the body 11 (a surface in contact with the top surface of a storage container or table).

Though the cap 12 which closes the supply hole 11b may be simple one, it is preferable that the cap 12 has a connection piece 15 formed as one unit fastened to a bottom surface of the body 11 for preventing the cap 12 from losing for closing the supply hole 11b again when the paste filled in the body 11 is not used at a time.

FIGS. 4 and 5, which illustrate an embodiment of the present invention, show an example in which one end of the connection piece 15 fastened to the bottom surface of the body 11.

If a boss 16 having a holding hole 16a is formed on the recessed portion 13 of the body 11, a ball 17 is formed on the connection piece 15, which will be placed in the holding hole 16a, and the ball 17 is pressed fit in the holding hole 16a to make the ball 17 deformed and inserted in the holding hole 16a without requiring separate jig, the cap 12 can become movable around the ball 17.

There is a press member 18 movably mounted in the body 11, and includes a flange 18a, a rim 18b, a sloped portion 18c and a deforming portion 18d both continuous from the rim 18b inwardly, for serving as a cover in storage and transportation and moving inwardly by a pressing force of a pusher 19 in a state the container is loaded on the paste printer. In this instance, the rim 18b is in close contact with an inside circumference of the body 11 for the press member to serve as a piston.

Since a material of the press member 18 will be selected such that the press member 18 enables to serve as a cover in storage and transportation and to serve as the piston as the member 18 is deformed by the pressing force of a pusher 19, the material of the press member 18 will not be defined.

FIG. 6 illustrates a cross sectional view of a pressing member in accordance with an embodiment of the present invention.

Referring to FIG. 6, a structure of the pressing member 18 enables a rim 18b to make close contact with an inside circumferential surface of the body 11 even without a flange. This type of press member 18 also is adequate to serve as a cover in a general state and serves as a piston in a process the paste 3 is supplied, automatically.

It is preferable that an angle between the rim 18b and the sloped portion 18c of the press member 18 is 30˜40°.

If the angle between the rim 18b and the sloped portion 18c is smaller than 30°, deformation of a portion in contact with the inside circumferential surface of the body 11 becomes greater in a process the press member 18 is pressed down and deformed by the pusher 19, to make the press member 18 to fail secure pressing down of the paste, leaving the paste 3 on the inside circumferential surface of the body 11, and permitting leaking of the paste 3 between the inside circumferential surface of the body 11 and a contact surface of the press member 18 if severe.

If the angle between the rim 18b and the sloped portion 18c is greater than 40°, while deformation of the portion in contact with the inside circumferential surface of the body 11 is small in a process the press member 18 is pressed down and deformed by the pusher 19, because a diameter of the supply hole 11b through which the paste 3 is discharged following the pressing down of the pusher 19 on the press member 18 is small to exert a high pressure to the inside of the body 11, to break or deform the body 11, it is preferable that the angle of the sloped portion is 30˜40°.

If the recessed portion 13 is formed in the bottom of the body 11, it is preferable that a bottom surface of the press member 18 has a recessed portion 20 in conformity with the recessed portion 13 in the body 11.

This is for full discharge of the paste 3 from the body 11 through the supply hole 11b as the bottom of the body 11 and the bottom surface of the press member 18 are in conformity with each other.

However, referring to FIG. 7, which illustrates another embodiment of the present invention, when the bottom of the body 11 is flat owing to formation of the annular ring 14, it is evident that the recessed portion in the bottom surface of the press member 18 is not required, but the press member 18 has a flat bottom surface, too.

The operation of the container for automatically dispensing paste in a paste printer according to the present invention will be described.

Referring to FIG. 5A, when it is intended to store or transport the paste 3 in the body 11, the supply hole 11b in the bottom of the body 11 is closed with the cap 12, to prevent the paste 3 from being discharged or from setting caused by contact with air.

In this state, if it is intended to make automatic dispensing of the paste 3 to the stencil 2 of the paste printer from the body 11, the body 11 is clamped over the stencil 2 with known clamping means (not shown).

Then, after removing the cap 12 to open the supply hole 11b, the ball 17 placed in the holding hole 16a in the boss 16 is turned to place the cap 12, connected to the ball 17 with the connection piece 15, away from the supply hole 11b so that the paste 3 being discharged through the supply hole 11b does not interfere with the cap 12.

In this instance, since no external force is applied to the press member 18 that closes the opening 11a, the press member 18 serves as a cover.

In this state, if the pusher 19 is moved down by a predetermined stroke with a cylinder (not shown) for automatic supply of the paste 3 to the upper surface of the stencil 2 from the body 11, because the deforming portion 18d of the press member 18 is deformed by the pressing force of the pusher to deform and move down the flange 18a of the press member 18, covering the body, into the body 11 as shown in FIG. 5B, the rim 18b is brought into close contact with the inside circumferential surface of the body 11, forming a shape similar to a piston.

In case of the press member 18 shown in FIG. 6 as another embodiment of the present invention, when the pusher 19 pushes a central portion of the press member 18, the rim 18b is deformed outwardly such that a point the rim 18b and the sloped portion 18c meets, i.e., a portion of the rim 18b that meets with the inside circumferential surface of the body, makes close contact with the inside circumferential surface of the body.

Along with this, if the press member 18 moves down by a predetermined stroke owing to the pressing force of the pusher 19, the paste 3 is supplied from the body 11 to the upper surface of the stencil 2 by a fixed amount through the supply hole 11b in the bottom of the body 11.

The amount of the paste 3 can be fixed by adjusting the stroke of the press member 18 which moves down by the pressing force of the pusher 19.

When it is intended to stop the supply of the paste 3 for a time period due to maintenance of the printer or finish of the printing in the middle of accurate dispensing of the paste 3 to the upper surface of the stencil 2 according to above operation, if the supply hole 11b is closed with the cap 12, setting of the paste 3 in the body 11 is prevented as the press member 18 which serves as the piston closes the opening 11a of the body 11.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A container for automatically dispensing paste in a paste printer for supplying paste to an upper surface of a stencil, comprising:
a body including;
an opening,
a supply hole in a center of a bottom for supply of the paste, and
a cap for closing the supply hole in case of storage or transportation, and opening the supply hole in case of loading the body on the paste printer; and
a press member movably mounted in the body, including;
a rim, and
a sloped portion and a deforming portion both continuous from the rim inwardly, for serving as a cover in storage and transportation and moving inwardly by a pressing force of a pusher such that the rim is in close contact with an inside surface of the body for the press member to serve as a piston in a state the container is loaded on the paste printer, thereby automatically dispensing the paste to the upper surface of the stencil through the supply hole.

2. The container as claimed in claim 1, wherein the press member further includes a flange formed as one unit, the flange being in contact with a top surface of the body.

3. The container as claimed in claim 2, wherein the rim has an angle of 30˜40° to a surface of the sloped portion.

4. The container as claimed in claim 1, wherein the rim has an angle of 30˜40° to a surface of the sloped portion.

5. The container as claimed in claim 1, wherein the body further includes an inwardly curved recessed portion in a center of a bottom, and the cap has a connection piece formed as one unit with the cap, the connection piece being fastened to the recessed portion.

6. The container as claimed in claim 5, wherein the press member further includes a recessed portion in a bottom surface thereof to be in conformity with the recessed portion of the body.

7. The container as claimed in claim 5, wherein the recessed portion is provided with a boss having a holding hole in the recessed portion, and the connection piece is provided with a ball fixably fitted into the holding hole, so that the ball can be rotatably fitted into the holding hole.

8. The container as claimed in claim 1, wherein the body further includes an annular ring projected from a bottom surface of the body, and the cap has a connection piece formed as one unit, the connection piece being fastened to a recessed portion of the annular portion.

9. The container as claimed in claim 8, wherein the recessed portion is provided with a boss having a holding hole in the recessed portion, and the connection piece is provided with a ball fixably fitted into the holding hole, so that the ball can be rotatably fitted into the holding hole.
